(19) United States
(12) Patent Application Publication
(10) Pub. No.: US 2015/0107887 A1
(43) Pub. Date: Apr. 23, 2015

(54) ELECTRIC-ELEMENT MOUNT SEAT

(71) Applicant: BOTHHAND ENTERPRISE INC., Tainan City (TW)

(72) Inventor: Chang-Liang LIN, Taoyuan County (TW)

(73) Assignee: BOTHHAND ENTERPRISE INC., Tainan City (TW)

(21) Appl. No.: 14/280,267

(22) Filed: May 16, 2014

(30) Foreign Application Priority Data
Oct. 21, 2013 (TW) 102219588

(51) Int. Cl. H01L 23/495

(52) U.S. Cl. CPC H01L 23/49517
USPC 174/261

(57) ABSTRACT

An electric-element mount seat adapted to receive at least one electric element is disclosed. The electric-element mount seat includes a seat body that has a base wall and two opposite side walls extending from the base wall, and a plurality of pins that are separately disposed on the side walls of the seat body in a plug-in manner. Each of the pins includes a wire-wrapped section adapted to be electrically connected to the electric element. The wire-wrapped section has a rod portion that protrudes from the bottom surface of a corresponding one of the side walls in a top-down direction and a hook portion that extends from the rod portion and that is bent toward the rod portion.

### CROSS-REFERENCE TO RELATED APPLICATION

This application claims priority to Taiwanese Application No. 102219588, filed on Oct. 21, 2013.

### BACKGROUND OF THE INVENTION

1. Field of the Invention

The invention relates to an electric-element mount seat, more particularly to an electric-element mount seat including a plurality of pins respectively formed with hook portions.

2. Description of the Related Art

Recently, with vigorous development of the technical industry, electronic products are increasingly compact and may be provided with a plurality of electronic devices, such as a filter for eliminating interfering signals and enhancing desired signals. A conventional electronic device generally includes a mount seat and at least one electric element. The mount seat has a seat body for accommodating the electric element and a plurality of pins that are separately disposed on two sides of the seat body. The electric element may have a doughnut-shaped core separately wrapped with two wires that are electrically connected to two of the pins, respectively.

Since the electronic products have a trend towards light weight and compactness, the design of the mount seats also has a trend towards miniaturization. The miniaturized structure of the mount seats makes an arrangement of the pins be too dense to achieve effective separation of the wires. Besides, the structure of the conventional pins also needs to be improved in order to reliably secure the wires.

### SUMMARY OF THE INVENTION

Therefore, an object of the present invention is to provide an electric-element mount seat that can alleviate the aforesaid drawbacks of the prior art.

According to the present invention, an electric-element mount seat adapted to receive at least one electric element includes a seat body and a plurality of pins.

The seat body has a base wall and two opposite side walls that extend from the base wall. Each of the side walls has an inner surface that is adapted for facing the electric element, an outer surface that is opposite to the inner surface, and a bottom surface that is connected between the inner and outer surfaces and that is distant from the base wall.

The pins are separately disposed on the side walls of the seat body in a plug-in manner. Each of the pins has a wire-wrapped section that is adapted to be electrically connected to the electric element. The wire-wrapped section has a rod portion that protrudes from the bottom surface of a corresponding one of the side walls in a top-down direction and a hook portion that extends from the rod portion and that is bent toward the rod portion.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view of the preferred embodiment of an electric-element mount seat according to the present invention;

FIG. 2 is a schematic sectional view of the preferred embodiment of FIG. 1; and

FIG. 3 is a partly enlarged view of the preferred embodiment of FIG. 1.

### DETAILED DESCRIPTION OF THE PREFERRED EMBODIMENT

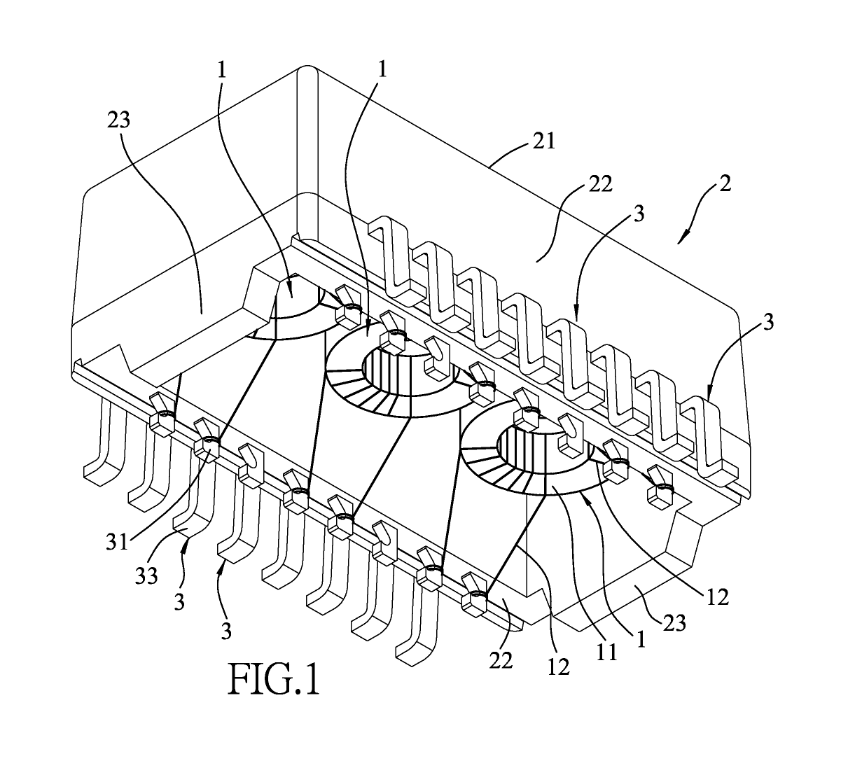

Referring to FIG. 1, the preferred embodiment of an electric-element mount seat adapted to receive at least one electric element according to this invention is shown to receive three electric elements 1. Each of the electric elements 1 includes a doughnut-shaped core 11 and two wires 12 that are separately wrapped around the doughnut-shaped core 11 for a plurality of turns. The configuration, type, number and arrangement of the electric elements 1 are not limited to those shown in FIG. 1 and can be modified and varied by a skilled artisan based on intended applications in light of the disclosure of this invention.

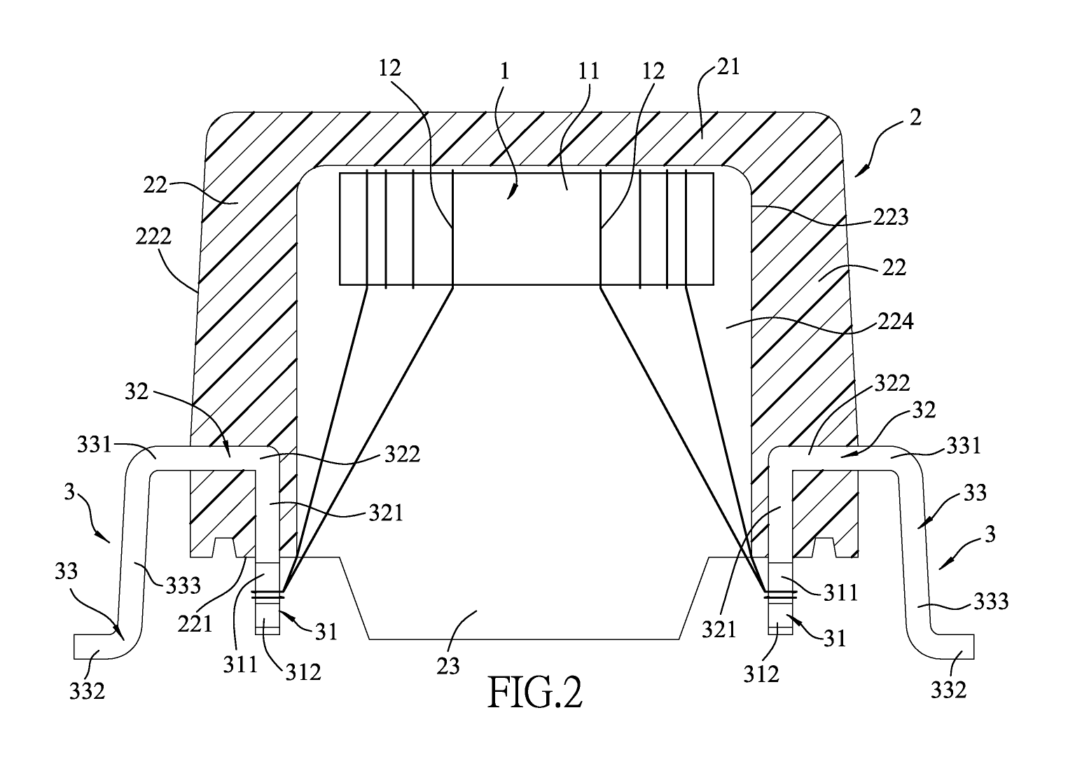

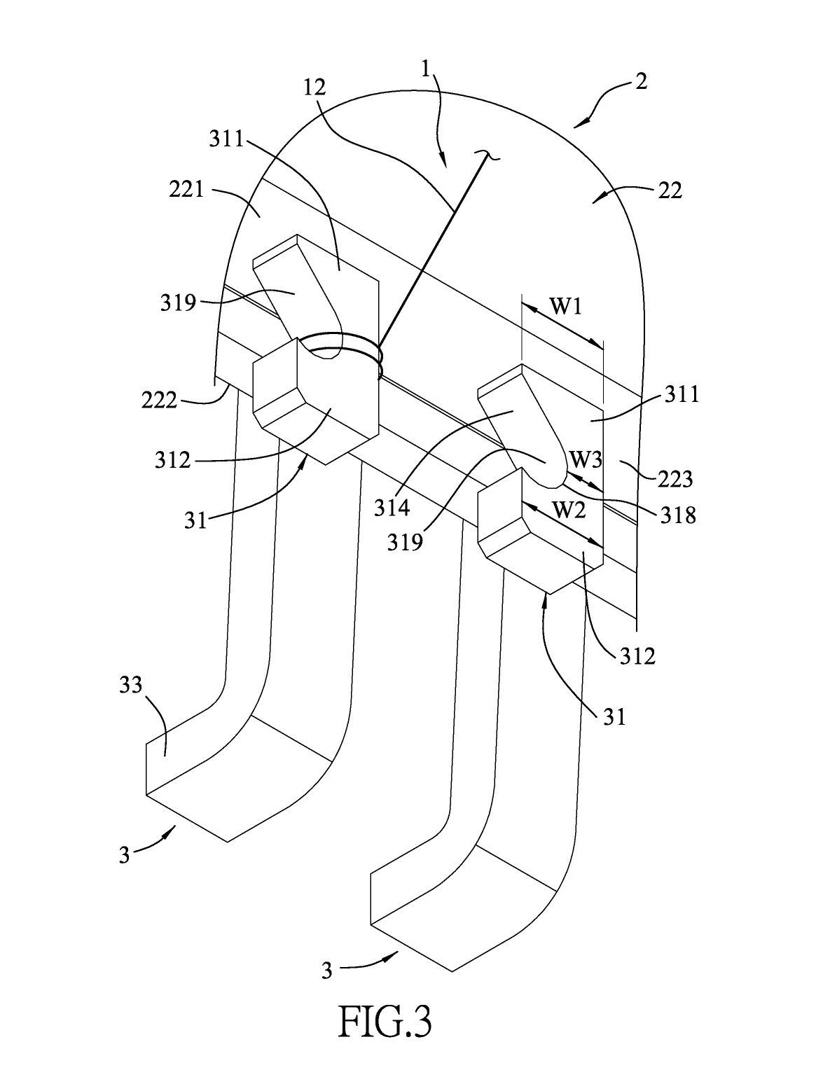

Further referring to FIGS. 2 and 3, the electric-element mount seat includes a seat body 2 that may be made from a plastic material, and a plurality of pins 3 that may be made from a metallic material.

The seat body 2 includes abase wall 21, two opposite side walls 22 extending from the base wall 21, and two opposite end walls 23 extending from the base wall 21 and each connected between the side walls 22. The base wall 21, the side walls 22 and the end walls 23 cooperate with each other to define an inner space 224 for accommodating the electric elements 1. The inner space 224 has a U-shaped cross section in the orientation shown in FIGS. 1 and 2. Each of the side walls 22 has an inner surface 223 facing the electric elements 1, an outer surface 222 opposite to the inner surface 223 and a bottom surface 221 connected between the inner and outer surfaces 223, 222 and distant from the base wall 21.

The pins 3 are separately disposed on the side walls 22 of the seat body 2 in a plug-in manner. Each of the pins 3 includes a wire-wrapped section 31 adapted to be electrically connected to a corresponding one of the electric elements 1. The wire-wrapped section 31 has a rod portion 311 that protrudes from the bottom surface 221 of a corresponding one of the side walls 22 in a top-down direction and a hook portion 312 that extends from the rod portion 311 and that is bent toward the rod portion 311.

Preferably, each of the pins 3 further includes an embedded section 32 and a mounting section 33. The embedded section 32 has two arms 321, 322 substantially perpendicular to each other. The arm 321 is connected to the wire-wrapped section 31. The embedded section 32 is plugged in the corresponding one of the side walls 22. The mounting section 33 protrudes out of the corresponding one of the side wall 22 and is connected to the arm 322 of the embedded section 32.

Preferably, the mounting section 33 has two ends 331, 332 extending away from each other in a left-right direction that is perpendicular to the top-down direction, and an intermediate portion 333 connected between the two ends 331, 332 and extending in the top-down direction. The end 331 is connected to the arm 322 of the embedded section 32.

Preferably, the rod portion 311 of the wire-wrapped section 31 of each of the pins 3 has a width decreasing in the top-down direction, and the hook portion 312 has a width increasing in the top-down direction. The decreasing width of the rod portion 311 has a maximum value (W1) substantially equal to a maximum value (W2) of the increasing width of the hook portion 312. The rod portion 311 cooperates with the hook portion 312 to define a groove 319 that has a front-facing opening. More preferably, the groove 319 is configured by a curve face 318 that is formed on the hook portion 312 and an inclined face 314 that extends from the curve face 318 and formed on the rod portion 311. The inclined face 314 assists in easy slipping of the corresponding wire 12 into the groove 319 of the wire-wrapped section 31 and the curve face 318 assists in securing of said wire 12 on the wire-wrapped section 31.

Preferably, the maximum value (W1) of the rod portion 311 and the maximum value (W2) of the increasing width of the hook portion 312 are both about 0.46 mm. The decreasing width of the rod portion 311 has a minimum value (W3) of about 0.26 mm.

Preferably, the curve face 318 of the groove 319 has a curvature of about 0.16 mm.

Preferably, the wire-wrapped section 31 of each of the pins 3 has a length in the top-down direction ranging from 0.2 mm to 3.0 mm, and more preferably, of 0.8 mm.

When the electric-element mount seat and the electric elements 1 are assembled, the electric elements 1 are arranged in a row and disposed on the base wall 21 within the inner space 224. The two wires 12 wrapped around each of the electric elements 1 are respectively pulled toward the wire-wrapped sections 31 of two corresponding opposite ones of the pins 3. Then, the wires 12 are respectively extended through the grooves 319 of the wire-wrapped sections 31, wrapped around the wire-wrapped sections 31 and retained by the hook portions 312 so as to be separately secured on the corresponding opposite pins 3. Slipping of the wires 12 from the pins 3 can be avoided. When a soldering operation for electrically connecting the pins 3 using a tin solder is subsequently conducted, interference among the wires 12 can be avoided. The electric-element mount seat thus formed maybe further encapsulated with an insulating material (not shown) and be provided with a cover (not shown) so as to form an integrated package.

In view of the foregoing, by virtue of the structural configuration of the electric-element mount seat of this invention, the arrangement of the pins 3 is able to achieve effective separation of the wires 12 and the wires 12 are reliably secured on the pins 3. Interference among the wires 12 and short circuit of the electric elements 1 can be avoided.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. An electric-element mount seat adapted to receive at least one electric element, comprising:
a seat body including a base wall and two opposite side walls extending from said base wall, each of said side walls having an inner surface adapted for facing the electric element, an outer surface opposite to said inner surface and a bottom surface connected between said inner and outer surfaces and distant from said base wall; and
a plurality of pins that are separately disposed on said side walls of said seat body in a plug-in manner, each of said pins including a wire-wrapped section adapted to be electrically connected to the electric element, said wire-wrapped section having a rod portion that protrudes from said bottom surface of a corresponding one of said side walls in a top-down direction and a hook portion that extends from said rod portion and that is bent toward said rod portion.

2. The electric-element mount seat of claim 1, wherein said rod portion of said wire-wrapped section of each of said pins has a width decreasing in the top-down direction, and said hook portion has a width increasing in the top-down direction, said decreasing width of said rod portion having a maximum value substantially equal to a maximum value of said increasing width of said hook portion, said rod portion cooperating with said hook portion to define a groove that has a front-facing opening.

3. The electric-element mount seat of claim 2, wherein said groove is configured by a curve face that is formed on said hook portion and an inclined face that extends from said curve face and that is formed on said rod portion.

4. The electric-element mount seat of claim 2, wherein the maximum value of the decreasing width of the rod portion is about 0.46 mm, the decreasing width of said rod portion having a minimum value of about 0.26 mm.

5. The electric-element mount seat of claim 3, wherein said curve face of said groove has a curvature of about 0.16 mm.

6. The electric-element mount seat of claim 1, wherein said wire-wrapped section of each of said pins has a length in the top-down direction ranging from 0.2 mm to 3.0 mm.

7. The electric-element mount seat of claim 1, wherein the length is 0.8 mm.

8. The electric-element mount seat of claim 1, wherein each of said pins further includes: an embedded section that has two arms substantially perpendicular to each other, one of which is connected to said wire-wrapped section and is plugged in the corresponding one of said side walls; and a mounting section that protrudes out of said corresponding one of said side wall and that is connected to the other of said arms of said embedded section.

9. The electric-element mount seat of claim 6, wherein said mounting section has two ends extending away from each other in a left-right direction perpendicular to the top-down direction, and an intermediate portion connected between said two ends and extending in the top-down direction.
